(19) United States
(12) Patent Application Publication
(10) Pub. No.: US 2011/0070373 A1
(43) Pub. Date: Mar. 24, 2011

(54) METHOD FOR FORMING AN ORDERED ALLOY

(75) Inventors: Shien-Wen Wang, Taipei (TW); An-Cheng Sun, Taipei (TW); Jen-Hwa Hsu, Taipei (TW); Po-Cheng Kuo, Taipei (TW); Ching-Ray Chang, Taipei (TW)

(73) Assignee: National Taiwan University, Taipei (TW)

(21) Appl. No.: 12/700,953

(22) Filed: Feb. 5, 2010

(30) Foreign Application Priority Data
Sep. 23, 2009 (TW) 098132055

(51) Int. Cl. B05D 3/02; C23C 14/34

(52) U.S. Cl. 427/376.7; 204/192.12; 204/192.15

(57) ABSTRACT

A method for forming an ordered alloy includes: (a) forming a layer of a first metal with a layer thickness of less than 0.3 nm over a substrate; (b) forming a layer of a second metal with a layer thickness of less than 0.3 nm on the layer of the first metal under an elevated temperature sufficient to cause interdiffusion of atoms of the first and second metals between the layer of the first metal and the layer of the second metal so as to form the ordered alloy; and (c) repeating steps (a) and (b) until a predetermined layer thickness of the ordered alloy is achieved.

### CROSS-REFERENCE TO RELATED APPLICATION

This application claims priority of Taiwanese application No. 098132055, filed on Sep. 23, 2009.

### BACKGROUND OF THE INVENTION

1. Field of the Invention

This invention relates to a method for forming an ordered alloy, more particularly to a method involving forming layers of a first metal and layers of a second metal alternately disposed with the layers of the first metal under an elevated temperature.

2. Description of the Related Art

In the magnetic recording technology, perpendicular magnetic recording (PMR) materials have been successfully developed to achieve a high recording density. It is known in the art that FePt alloy having an ordered phase (or L1₀ phase), i.e., a face-centered tetragonal (FCT) crystal structure, exhibits a high magnetocrystalline anisotropy (MCA) and thus can be used in a PMR medium to enhance the thermal stability of the PMR medium. In addition, the ordered FePT alloy has an out-of-plane coercive field (Hc_{⊥}) and an out-of-plane squareness (S_{⊥}) higher than the requirements of a satisfactory PMR medium, which are respectively required to be higher than 1.0 kOe and 0.5. FePt alloy films used in the PMR medium are usually formed by sputtering techniques. The FePt alloy films thus formed normally have a disordered phase, i.e., a face-centered cubic (FCC) structure. Conventionally, the disordered FePt alloy is required to be annealed under a temperature of above 400° C. so as to be transformed from the FCC structure into the FCT structure and to be used in the PMR medium. However, the annealing temperature is too high and can result in problems, such as damage to semiconductor components to which the PMR medium is integrated, and an increase in the capital cost for making the PMR medium.

### SUMMARY OF THE INVENTION

Therefore, the object of the present invention is to provide a method for forming an ordered alloy that can overcome the aforesaid drawback of the prior art.

According to this invention, there is provided a method for forming an ordered alloy that comprises: (a) forming a layer of a first metal with a layer thickness of less than 0.3 nm over a substrate; (b) forming a layer of a second metal with a layer thickness of less than 0.3 nm on the layer of the first metal under an elevated temperature sufficient to cause interdiffusion of atoms of the first and second metals between the layer of the first metal and the layer of the second metal so as to form the ordered alloy; and (c) repeating steps (a) and (b) until a predetermined layer thickness of the ordered alloy is achieved.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 illustrates consecutive steps of the preferred embodiment of a method for making an ordered alloy according to this invention;

FIG. 2 is a fragmentary partly sectional view of a sputtering chamber to illustrate a state in which a substrate is disposed at a first position in the sputtering chamber;

FIG. 3 is a fragmentary partly sectional view of the sputtering chamber to illustrate a state in which the substrate is disposed at a second position in the sputtering chamber;

FIG. 4 is a sectional view taken along line IV-IV of FIG. 2;

FIG. 5 is a sectional view taken along line V-V of FIG. 3;

FIG. 6 illustrates a lattice structure of a unit cell of an ordered FePt alloy;

FIG. 7 is a hysteresis-loop plot to illustrate the magnetic property of a FePt alloy of Example 1 (E1);

FIG. 8 is anX-Ray Diffraction (XRD) plot to illustrate the crystal structure of the FePt alloy of Example 1 (E1);

FIG. 9 is a hysteresis-loop plot to illustrate the magnetic property of a FePt alloy of Example 2 (E2);

FIG. 10 is a hysteresis-loop plot to illustrate the magnetic property of a FePt alloy of Example 3 (E3);

FIG. 11 is a hysteresis-loop plot to illustrate the magnetic property of a FePt alloy of Example 4 (E4);

FIG. 12 is a hysteresis-loop plot to illustrate the magnetic property of a FePt alloy of Example 5 (E5);

FIG. 13 is a hysteresis-loop plot to illustrate the magnetic property of a FePt alloy of Example 6 (E6);

FIG. 14 is a hysteresis-loop plot to illustrate the magnetic property of a FePt alloy of Example 7 (E7);

FIG. 15 is a hysteresis-loop plot to illustrate the magnetic property of a FePt alloy of Example 8 (E8);

FIG. 16 is an XRD plot to illustrate the crystal structures of the FePt alloy of Examples 4˜8 (E4˜E8);

FIG. 17 is a hysteresis-loop plot to illustrate the magnetic property of a FePt alloy of Example 9 (E9); and

FIG. 18 is a hysteresis-loop plot to illustrate the magnetic property of a FePt alloy of the comparative example (CE).

### DETAILED DESCRIPTION OF THE PREFERRED EMBODIMENTS

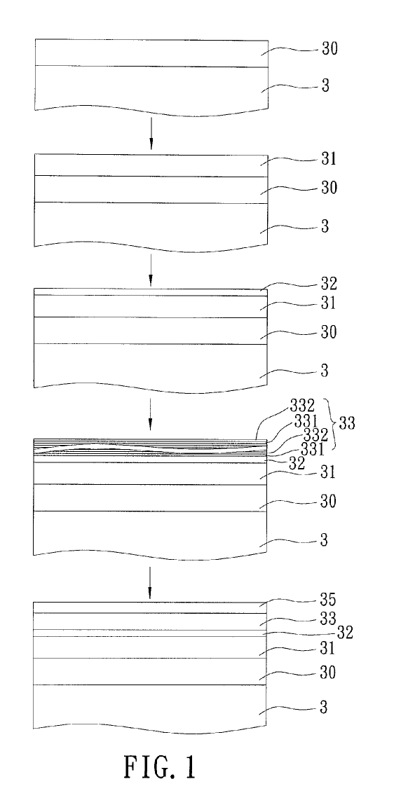

Referring to FIG. 1, the preferred embodiment of a method for forming an ordered alloy 33 is included in a process for making a perpendicular magnetic recording medium. The process includes: forming a soft magnetic underlayer 30 on a substrate 3; forming a first interlayer 31 made from Cr, MgO, or Cr alloy on the soft magnetic underlayer 30; forming a second interlayer 32 made from Pt on the first interlayer 31; forming a layer 331 of a first metal with a layer thickness of less than 0.3 nm on the second interlayer 32; forming a layer 332 of a second metal with a layer thickness of less than 0.3 nm on the layer 331 of the first metal under an elevated temperature sufficient to cause interdiffusion of atoms of the first and second metals between the layer 331 of the first metal and the layer 332 of the second metal so as to form the ordered alloy 33; repeating the steps of forming the layers 331, 332 alternately until a predetermined layer thickness of the ordered alloy 33, which is suitable as a magnetic recording material, is achieved; and forming a protective layer 35 on the ordered alloy 33.

Preferably, the layer thickness of each of the layers 331 of the first metal and the layers 332 of the second metal is greater than 0.01 nm and less than 0.3 nm.

Preferably, the first metal is Fe, Co, Ni, Mn, Au, or Cu, and the second metal is Pt, Pd, Cr, Al, or Cu with the proviso that the first metal and the second metal cannot be Cu at the same time. More preferably, the first metal is Fe, Co, or Ni, and the second metal is Pt, Pd, or Cr.

Preferably, formation of the ordered alloy 33 is performed by sputtering techniques.

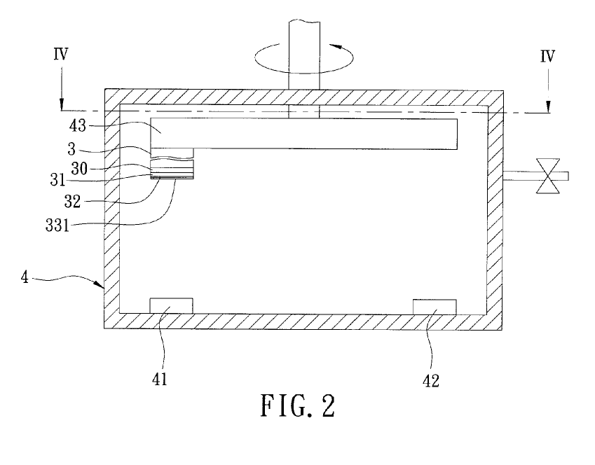

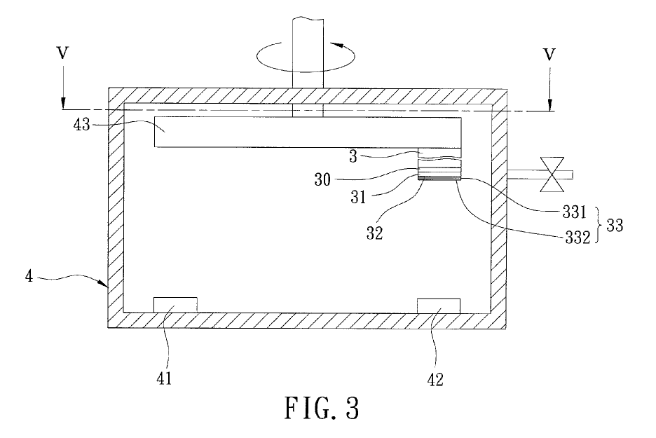

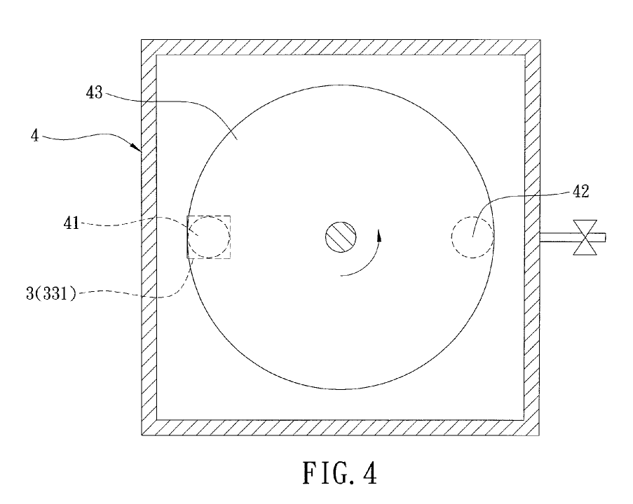

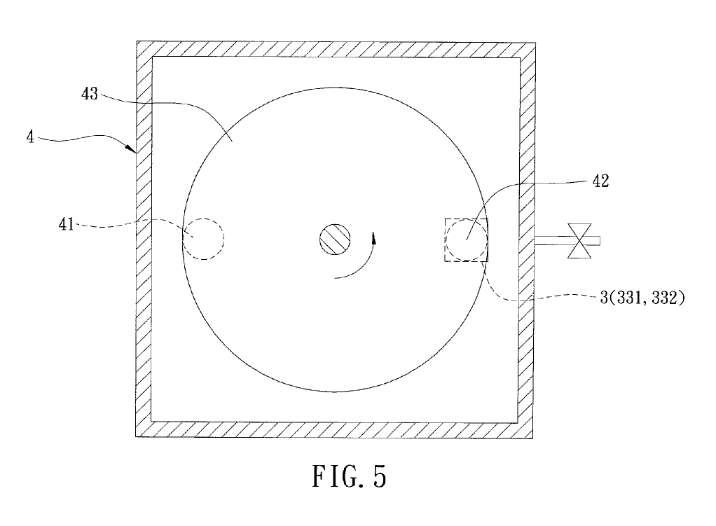

Referring to FIGS. 2 to 5, the sputtering is conducted in a manner that the substrate 3 is disposed movably in a sputtering chamber 4 so as to be alternately disposed between a first position (see FIG. 2), in which the substrate 3 is aligned with a target 41 of the first metal, and a second position (see FIG. 3), in which the substrate 3 is aligned with a target 42 of the second metal, thereby alternately forming layers 331 of the first metal and layers 332 of the second metal on the second interlayer 32. Preferably, the substrate 3 is carried by a rotatable carrier 43 provided in the sputtering chamber 4 so as to be rotatable and disposable alternately between the first and second positions.

When the first metal and the second metal are respectively Fe and Pt, the following conditions are preferable: the elevated temperature ranges from 300° C. to 350° C., the carrier 43 has a rotation speed ranging from 1 rpm to 20 rpm during the sputtering, and the sputtering is conducted by applying an output power ranging from 20 W to 70 W to the target 41 of the first metal (Fe) and an output power ranging from 10 W to 36 W to the target 42 of the second metal (Pt). When the elevated temperature is 350° C., the following conditions are more preferable: the carrier 43 has a rotation speed ranging from 10 rpm to 20 rpm during the sputtering, and the layer thickness of each of the layers 331 of the first metal (Fe) and the layers 332 of the second metal (Pt) ranges from 0.014 nm to 0.12 nm.

When the output power applied to each of the targets 41, 42 is increased, the deposition rate of each of the layers 331, 332 is increased correspondingly. In addition, when the rotation speed of the carrier 43 is increased, the layer thickness of each of the layers 331, 332 is decreased correspondingly due to a shorter time period for the substrate 3 to stay at the first and second positions. Hence, the layer thickness of each of the layers 331, 332 can be controlled by adjusting the rotation speed of the carrier 43 and/or the output power applied to the targets 41, 42.

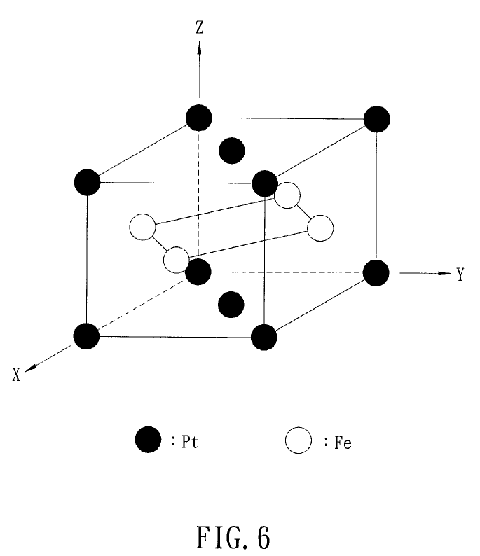

FIG. 6 illustrates the lattice structure of a unit cell of an ordered FePt alloy (the L1₀ phase). The lattice structure includes an upper layer of Pt atoms, a middle layer of Fe atoms, and a lower layer of Pt atoms. The upper, middle and lower layers are aligned along the z-axis, i.e., [001] direction. It is noted herein that the elevated temperature can be reduced by decreasing the layer thickness of each of the layers 331 of the first metal (Fe) and the layers 332 of the second metal (Pt), i.e., by decreasing the interdiffusion distance for Fe and Pt atoms to move to the lattice sites of Fe atoms and the lattice sites of Pt atoms of the L1₀ phase. Because of the reduced interdiffusion distance, the magnetic recording material formed of the aforesaid ordered alloy 33 exhibits superior [001]-preferred orientation (texture), thereby resulting in a high out-of-plane squareness.

The following examples and comparative example are provided to illustrate the merits of the preferred embodiments of the invention, and should not be construed as limiting the scope of the invention.

### Example 1 (E1)

A substrate 3 made from glass and having a size of 7 cm×7 cm was placed in a sputtering chamber. The substrate 3 was deposited with a first interlayer 31 of CrRu alloy with a layer thickness of 90 nm thereon under a working pressure of 5 mTorr and a substrate temperature of 300° C. A second interlayer 32 made from Pt and having a layer thickness of 2 nm was then formed on the first interlayer 31 by sputtering under a working pressure of 10 mTorr and a substrate temperature of 350° C. The substrate 3 formed with the first and second interlayers 31, 32 thereon was then mounted to a rotatable carrier 43 (which is in the form of a disc with a diameter of 50 cm) in a magnetron sputtering chamber 4 with targets of Fe and Pt (which have a size approximate to the size of the substrate 3) mounted diametrically therein. Sputtering was performed by applying an output power of 20 W to the target 41 of Fe and an output power of 10 W to the target 42 of Pt under an elevated temperature (i.e., annealing temperature) of 300° C. and a working pressure of 10 mTorr. The carrier 43 was operated at a rotation speed of 10 rpm to move the substrate 3 to the first and second positions alternately during sputtering. After sputtering, a total layer thickness of 20 nm of a FePt alloy 33 was obtained. The layer thickness of each of the layers 331 of Fe and the layers 332 of Pt of the FePt alloy was calculated based on the total layer thickness and the rotation speed of the carrier 43, and is shown in Table 1. The FePt alloy thus formed has a composition of Fe₄₈Pt₅₂ as determined by using energy dispersive spectrometry (EDS).

### Example 2 (E2)

A FePt alloy of Example 2 (E2) was prepared by steps and operating conditions similar to those of Example 1 (E1), except that the rotation speed of the carrier 43 was 5 rpm, and the elevated temperature was 350° C. Each of the layers 331 of Fe and the layers 332 of Pt thus formed has a layer thickness of 0.0578 nm (see Table 1). The FePt alloy thus formed has a composition of Fe₄₈Pt₅₂.

### Example 3 (E3)

A FePt alloy of Example 3 (E3) was prepared by steps and operating conditions similar to those of Example 2 (E2), except that the rotation speed of the carrier 43 was 20 rpm. Each of the layers 331 of Fe and the layers 332 of Pt thus formed has a layer thickness of 0.0145 nm (see Table 1). The FePt alloy thus formed has a composition of Fe₄₈Pt₅₂.

### Example 4 (E4)

A FePt alloy of Example 4 (E4) was prepared by steps and operating conditions similar to those of Example 1 (E1), except that the elevated temperature was 350° C. Each of the layers 331 of Fe and the layers 332 of Pt thus formed has a layer thickness of 0.0289 nm (see Table 1). The FePt alloy thus formed has a composition of Fe₄₈Pt₅₂.

### Example 5 (E5)

A FePt alloy of Example 5 (E5) was prepared by steps and operating conditions similar to those of Example 4 (E4), except that the output powers applied to the target 41 of Fe and target 42 of Pt were 40 W and 20 W, respectively. Each of the layers 331 of Fe and the layers 332 of Pt thus formed has a layer thickness of 0.0589 nm (see Table 1). The FePt alloy thus formed has a composition of Fe₄₈Pt₅₂.

### Example 6 (E6)

A FePt alloy of Example 6 (E6) was prepared by steps and operating conditions similar to those of Example 4 (E4), except that the output powers applied to the target 41 of Fe and target 42 of Pt were 50 W and 25 W, respectively. Each of the layers 331 of Fe and the layers 332 of Pt thus formed has a layer thickness of 0.0749 nm (see Table 1). The FePt alloy thus formed has a composition of Fe₄₈Pt₅₂.

### Example 7 (E7)

A FePt alloy of Example 7 (E7) was prepared by steps and operating conditions similar to those of Example 4 (E4), except that the output powers applied to the target 41 of Fe and target 42 of Pt were 60 W and 31 W, respectively. Each of the layers 331 of Fe and the layers 332 of Pt thus formed has a layer thickness of 0.0938 nm (see Table 1). The FePt alloy thus formed has a composition of Fe₄₈Pt₅₂.

### Example 8 (E8)

A FePt alloy of Example 8 (E8) was prepared by steps and operating conditions similar to those of Example 4 (E4), except that the output powers applied to the target 41 of Fe and target 42 of Pt were 70 W and 36 W, respectively. Each of the layers 331 of Fe and the layers 332 of Pt thus formed has a layer thickness of 0.1113 nm (see Table 1). The FePt alloy thus formed has a composition of Fe₄₈Pt₅₂.

### Example 9 (E9)

A FePt alloy of Example 9 (E9) was prepared by steps and operating conditions similar to those of Example 4 (E4), except that the rotation speed of the carrier 43 was 1 rpm. Each of the layers 331 of Fe and the layers 332 of Pt thus formed has a layer thickness of 0.289 nm (see Table 1). The FePt alloy thus formed has a composition of Fe₄₈Pt₅₂.

### Comparative Example (CE)

A FePt alloy of the comparative example was prepared by steps and operating conditions similar to those of Example 9 (E9), except that the output powers applied to the target 41 of Fe and target 42 of Pt were 40 W and 20 W, respectively. Each of the layers 331 of Fe and the layers 332 of Pt thus formed has a layer thickness of 0.5895 nm (see Table 1).

### <Analysis of the FePt Alloy>

The relationship between the applied magnetic field (Hₐ) and magnetization (M), i.e., hysteresis-loops, of the FePt alloy of each of Examples (E1˜E9) and the comparative example (CE) was measured using a vibrating sample magnetometer (VSM).

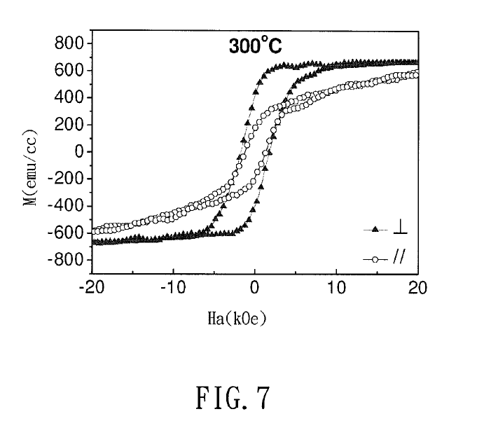

From the hysteresis-loop shown in FIG. 7, the coercive field (Hc_{┘}) and the squareness (S_{⊥}) of Example 1 (E1) are respectively 1740 Oe and 0.61 (see Table 1) under the elevated temperature of 300° C.

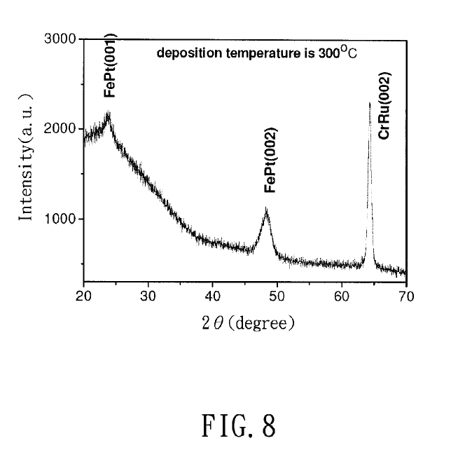

The XRD plot shown in FIG. 8, with reference to No. 43-1395 of JCPDF card (not shown), demonstrates that the FePt alloy of Example 1 (E1) has an L1₀ phase and a (001) preferred orientation texture.

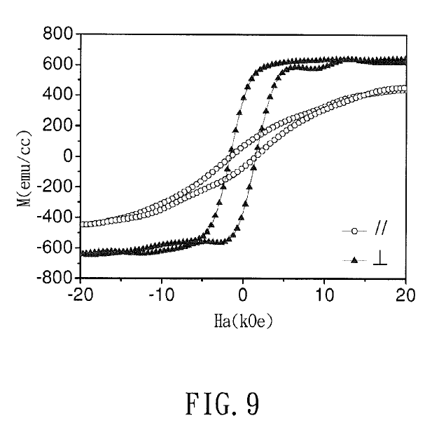

From the hysteresis-loop shown in FIG. 9, the coercive field (Hc_{⊥}) and the squareness (S_{⊥}) of Example 2 (E2) are 1575 Oe and 0.56 (see Table 1), respectively.

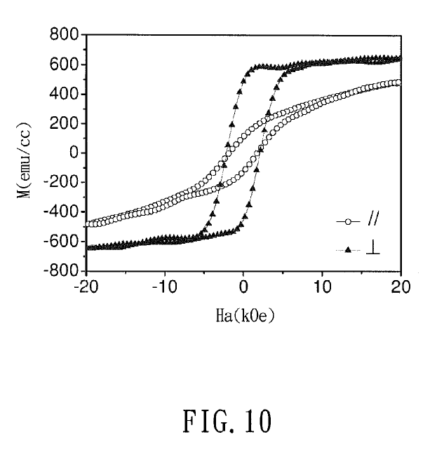

From the hysteresis-loop shown in FIG. 10, the coercive field (Hc_{⊥}) of Example 3 (E3) is 2125 Oe, and the squareness (S_{⊥}) of Example 3 (E3) is increased to 0.79 (see Table 1) as compared to Example 2.

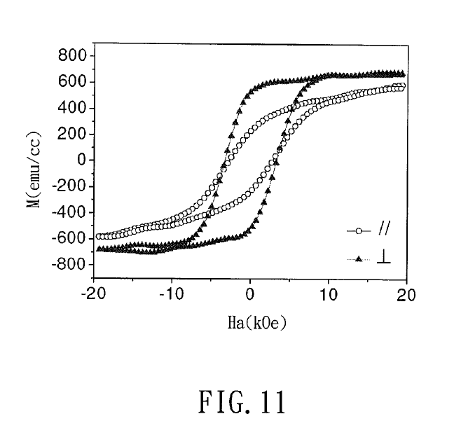

From the hysteresis-loop shown in FIG. 11, the coercive field (Hc_{⊥}) and the squareness (S_{⊥}) of Example 4 (E4) are 3320.59 Oe and 0.7935 (see Table 1), respectively.

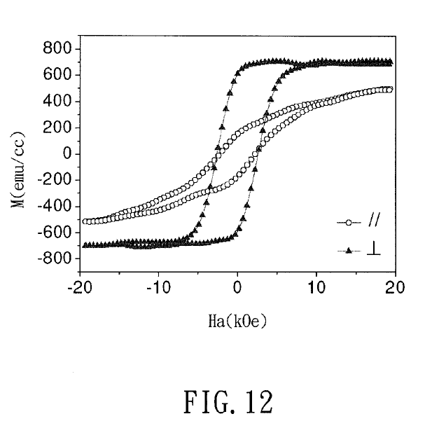

From the hysteresis-loop shown in FIG. 12, the coercive field (Hc_{⊥}) and the squareness (S_{⊥}) of Example 5 (E5) are 2567.30 Oe and 0.9387 (see Table 1), respectively.

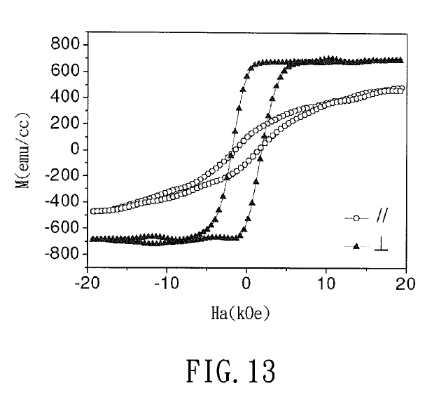

From the hysteresis-loop shown in FIG. 13, the coercive field (Hc_{⊥}) and the squareness (S_{⊥}) of Example 6 (E6) are 1842.40 Oe and 0.8993 (see Table 1), respectively.

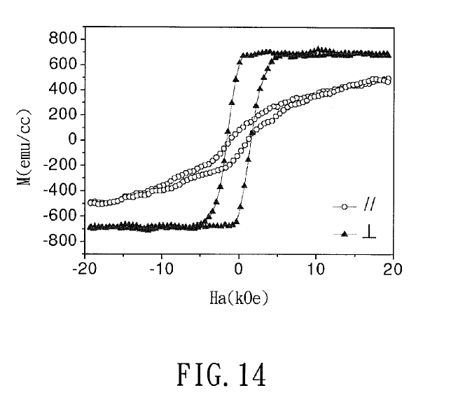

From the hysteresis-loop shown in FIG. 14, the coercive field (H_{⊥}) and the squareness (S_{⊥}) of Example 7 (E7) are 1576.96 Oe and 0.8584 (see Table 1), respectively.

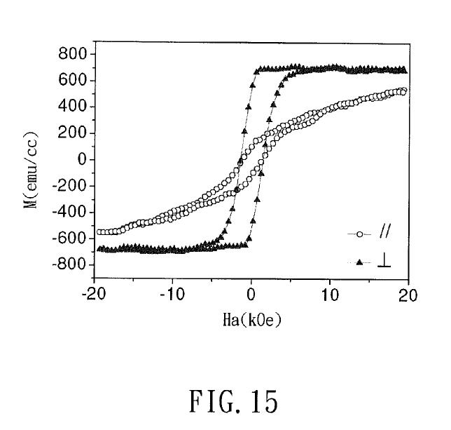

From the hysteresis-loop shown in FIG. 15, the coercive field (Hc_{⊥}) and the squareness (S_{⊥}) of Example 8 (E8) are 1430.86 Oe and 0.7725 (see Table 1), respectively.

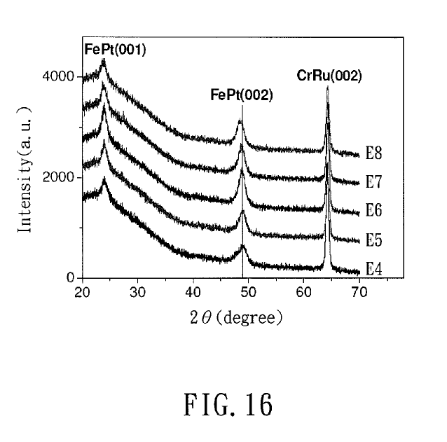

The XRD curves shown in FIG. 16, with reference to No. 43-1395 of JCPDF card (not shown), demonstrates that the FePt alloy of each of Examples 4˜8 (E4-E8) has an L1₀ phase and a (001) preferred orientation texture.

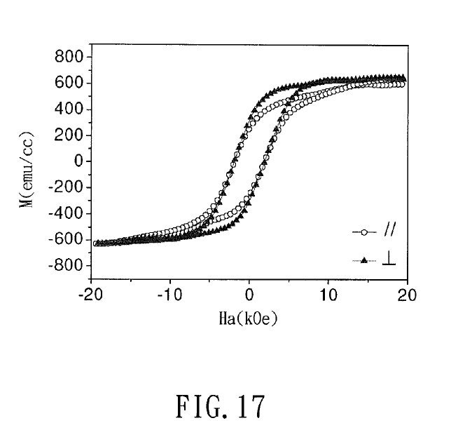

From the hysteresis-loop shown in FIG. 17, the coercive field (Hc_{⊥}) and the squareness (S_{⊥}) of Example 9 (E9) are 1923.35 Oe and 0.5570 (see Table 1), respectively.

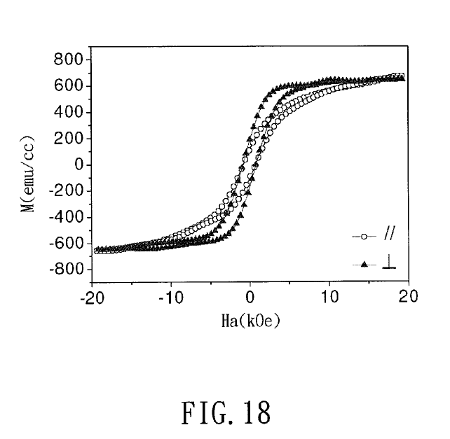

From the hysteresis-loop shown in FIG. 18, the coercive field (Hc_{⊥}) and the squareness (S_{⊥}) of Comparative Example (CE) are only 798.54 Oe and 0.3340 (see Table 1), respectively. This indicates that the metal alloy composed of layers 331 of Fe and layers 332 of Pt (each of the layers 331 and layers 332 having a layer thickness greater than 0.3 nm) cannot provide satisfactory Hc_{⊥} and S_{⊥} properties.

TABLE 1

| | | | Output power | | | | |
|---|---|---|---|---|---|---|---|
| | Thickness¹ | Speed² | (W) | | Temp.³ | Hc⊥ | |
| | (nm) | (rpm) | Fe | Pt | (° C.) | (Oe) | S⊥ |
| E1 | 0.0289 | 10 | 20 | 10 | 300 | 1740.00 | 0.6100 |
| E2 | 0.0578 | 5 | 20 | 10 | 350 | 1575.00 | 0.5600 |
| E3 | 0.0145 | 20 | 20 | 10 | 350 | 2125.00 | 0.7900 |
| E4 | 0.0289 | 10 | 20 | 10 | 350 | 3320.59 | 0.7935 |
| E5 | 0.0589 | 10 | 40 | 20 | 350 | 2567.30 | 0.9387 |
| E6 | 0.0749 | 10 | 50 | 25 | 350 | 1842.40 | 0.8993 |
| E7 | 0.0938 | 10 | 60 | 31 | 350 | 1576.96 | 0.8584 |
| E8 | 0.1113 | 10 | 70 | 36 | 350 | 1430.86 | 0.7725 |
| E9 | 0.2890 | 1 | 20 | 10 | 350 | 1923.35 | 0.5570 |
| CE | 0.5895 | 1 | 40 | 20 | 350 | 798.54 | 0.3440 |

¹layer thickness of each layer of Fe and Pt
²rotation speed of the carrier
³elevated temperature of the sputtering operation

In conclusion, by forming alternately each layer of Pt with the layer thickness of less than 0.3 nm and each layer of Fe with the layer thickness of less than 0.3 nm, the annealing temperature in the method of this invention for forming the ordered alloy can be reduced to below 400° C. so that the aforesaid drawback of requiring a high annealing temperature for forming an ordered alloy in the prior art can be eliminated. Moreover, the ordered alloy thus obtained exhibits satisfactory and good Hc_{⊥} and S_{⊥} properties.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for forming an ordered alloy, comprising:
(a) forming a layer of a first metal with a layer thickness of less than 0.3 nm over a substrate;
(b) forming a layer of a second metal with a layer thickness of less than 0.3 nm on the layer of the first metal under an elevated temperature sufficient to cause interdiffusion of atoms of the first and second metals between the layer of the first metal and the layer of the second metal so as to form the ordered alloy; and
(c) repeating steps (a) and (b) until a predetermined layer thickness of the ordered alloy is achieved.

2. The method of claim 1, wherein the layer thickness of each of the layers of the first metal and the layers of the second metal is greater than 0.01 nm and less than 0.3 nm.

3. The method of claim 1, wherein the first metal is Fe, Co, Ni, Mn, Au, or Cu, and the second metal is Pt, Pd, Cr, Al, or Cu with the proviso that the first metal and the second metal cannot be Cu at the same time.

4. The method of claim 3, wherein formation of the ordered alloy is performed by sputtering techniques.

5. The method of claim 4, wherein the first metal and the second metal are respectively Fe and Pt, the elevated temperature ranging from 300° C. to 350° C.

6. The method of claim 5, wherein the sputtering is conducted in a manner that the substrate is disposed movably in a sputtering chamber so as to be alternately disposed between a first position, in which the substrate is aligned with a target of the first metal, and a second position, in which the substrate is aligned with a target of the second metal.

7. The method of claim 6, wherein the substrate is carried by a rotatable carrier provided in the sputtering chamber so as to be rotatable and disposable alternately between the first and second positions, the carrier having a rotation speed ranging from 1 rpm to 20 rpm during the sputtering.

8. The method of claim 6, wherein the sputtering is conducted by applying an output power ranging from 20 W to 70 W to the target of the first metal and an output power ranging from 10 W to 36 W to the target of the second metal.
